(19) United States
(12) Patent Application Publication
(10) Pub. No.: US 2020/0071814 A1
(43) Pub. Date: Mar. 5, 2020

(54) EVAPORATION SOURCE

(71) Applicants: Chengdu BOE Optoelectronics Technology Co., Ltd., Chengdu (CN); BOE TECHNOLOGY GROUP CO., LTD., Beijing (CN)

(72) Inventors: Jinbiao Liu, Beijing (CN); Luoyang Feng, Beijing (CN); Youliang Li, Beijing (CN); Tianyu Xu, Beijing (CN); Rui Tan, Beijing (CN); Yongyong Wei, Beijing (CN); Xiang Liu, Beijing (CN); Li Chen, Beijing (CN); Kai Wen, Beijing (CN); Qinwen Jiang, Beijing (CN); Shangshu Sun, Beijing (CN); Peng Liu, Beijing (CN)

(21) Appl. No.: 16/396,734

(22) Filed: Apr. 28, 2019

(30) Foreign Application Priority Data
Aug. 28, 2018 (CN) 201810988636.X

(51) Int. Cl. C23C 14/24; H01L 51/56; C23C 14/12

(52) U.S. Cl. CPC C23C 14/243; H01L 2251/56; C23C 14/12; H01L 51/56

(57) ABSTRACT

An evaporation source includes a crucible and a heater for generating heat radiation. The crucible includes a crucible body and a nozzle disposed on a top surface of the crucible body. Except for the top surface of the crucible body, at least one side of the remaining sides of the crucible body is provided with a heat adjusting assembly. The heat adjusting assembly is configured for convecting heat radiation between the heat adjusting assembly and the crucible body. A gap exists between the heat adjusting assembly and the crucible body.

### CROSS REFERENCE TO RELATED APPLICATION

This application is based upon, and claims the benefit of and priority to, Chinese Patent Application No. 201810988636.X, filed on Aug. 28, 2018, where the entire contents thereof are incorporated herein by reference.

### TECHNICAL FIELD

The present disclosure relates to the field of evaporation technology, and more particularly, to an evaporation source.

### BACKGROUND

The Organic Light-Emitting Diode (OLED) device has various advantages, such as a simple fabrication process, adjustable color, low power consumption, etc., and, as such, there is a hot spot for development and investment in the field of display and illumination. With the increasing use of OLED display devices, their fabrication processes are becoming more mature. Currently, OLED devices are commonly used in a variety of ways including evaporation, inkjet printing, and thermal transfer. Among these methods of fabrication, the evaporation method is a relatively mature method and has been applied to mass production.

The evaporation process including heating the evaporation material under a certain vacuum condition so that the evaporation material is melted (sublimated) into a vapor composed of atoms, molecules, or atomic groups, and then condensed on the surface of the substrate to form a film, thereby forming a functional layer of the OLED device.

### SUMMARY

According to an aspect of the present disclosure, an evaporation source includes a crucible and a heater for generating heat radiation. The crucible includes a crucible body and a nozzle disposed on atop surface of the crucible body. A heat adjusting assembly is disposed on at least one of remaining sides except for the top surface of the crucible body. The heat adjusting assembly is configured to convect heat radiation between the heat adjusting assembly and the crucible body. A gap exists between the heat adjusting assembly and the crucible body.

Alternatively, the heat adjusting assembly includes a first heat adjusting member, wherein both the first heat adjusting member and the heater are disposed on a side surface of the crucible body, and the heater is disposed between the first heat adjusting member and the crucible body; wherein the side surface intersects with the top surface.

Alternatively, the crucible body is in a form of a rectangular parallelepiped, and the heater and the first heat adjusting member are disposed on a side of a side wall surrounded by a length and a height of the crucible body.

Alternatively, the first heat adjusting member includes a first reflection plate along an ejection direction of the crucible, and a height of the first reflection plate is lower than a height of the crucible body.

Alternatively, the first heat adjusting member further includes a control structure connected with the first reflection plate, wherein the control structure is configured to drive the first reflection plate to rotate so as to adjust an angle between the first reflection plate and a side surface corresponding to the first reflection plate.

Alternatively, the first reflection plate includes a plurality of first sub-plates independently controlled by the control structure.

Alternatively, the first reflection plate is a dual mirror plate.

Alternatively, the heat adjusting assembly includes a second heat adjusting member; wherein the second heat adjusting member is disposed on the bottom surface of the crucible body, and the bottom surface is disposed opposite to the top surface.

Alternatively, the second heat adjusting member includes a second reflection plate on which a hollowed-out pattern is provided.

Alternatively, a density of the hollowed-out pattern on the second reflection plate firstly increases and then decreases along an extending direction of the crucible body.

Alternatively, the second reflection plate includes a plurality of second sub-plates, and the hollowed-out pattern is provided on at least some of second sub-plates in the plurality of second sub-plates.

Alternatively, the evaporation source further includes a base provided with a groove; and the second reflection plate is disposed at an opening of the groove and faces a bottom of the groove.

### BRIEF DESCRIPTION OF THE DRAWINGS

In order to more clearly illustrate the embodiments of the present disclosure or the technical solutions in the prior art, the drawings to be used in the embodiments or the description of the prior art will be briefly described below. Understandably, the drawings in the following description are only certain embodiments of the present disclosure, and other drawings may be obtained from those skilled in the art without any creative work.

FIG. 1 is a schematic view of an evaporation process of an evaporation source provided by the related art.

FIG. 2 is a schematic structural view of an embodiment of an evaporation source according to an embodiment of the present disclosure.

FIG. 3 is a schematic structural view of another embodiment of an evaporation source according to an embodiment of the present disclosure.

FIG. 4 is a schematic structural view of another embodiment of an evaporation source according to an embodiment of the present disclosure.

FIG. 5 is a schematic structural view of another embodiment of an evaporation source according to an embodiment of the present disclosure.

FIG. 6 is a schematic view of an evaporation process of another embodiment of an evaporation source according to an embodiment of the present disclosure.

FIG. 7 is a schematic structural view of another embodiment of an evaporation source according to an embodiment of the present disclosure.

FIG. 8 is a schematic structural view of another embodiment of an evaporation source according to an embodiment of the present disclosure.

FIG. 9 is a schematic structural view of a second reflection plate in an evaporation source according to an embodiment of the present disclosure.

FIG. 10 is a schematic structural view of another second reflection plate in an evaporation source according to an embodiment of the present disclosure.

FIG. 11 is a schematic view showing a comparison between the evaporation effect of the evaporation source provided by an embodiment of the present disclosure and the evaporation effect of the evaporation source provided by the prior art.

FIG. 12 is a cross-sectional view taken along line A-A of FIG. 10.

FIG. 13 is a schematic structural view of another embodiment of an evaporation source according to an embodiment of the present disclosure.

FIG. 14 is a schematic structural view of another embodiment of an evaporation source according to an embodiment of the present disclosure.

### DETAILED DESCRIPTION

The technical solutions in the embodiments of the present disclosure are clearly and completely described in the following, with reference to the accompanying drawings in the embodiments of the present disclosure. It is understood that the described embodiments are only part of the embodiments of the present disclosure, i.e., do not include all of the embodiments. All other embodiments obtained by those skilled in the art based on the embodiments of the present disclosure without any creative work are within the scope of the present disclosure.

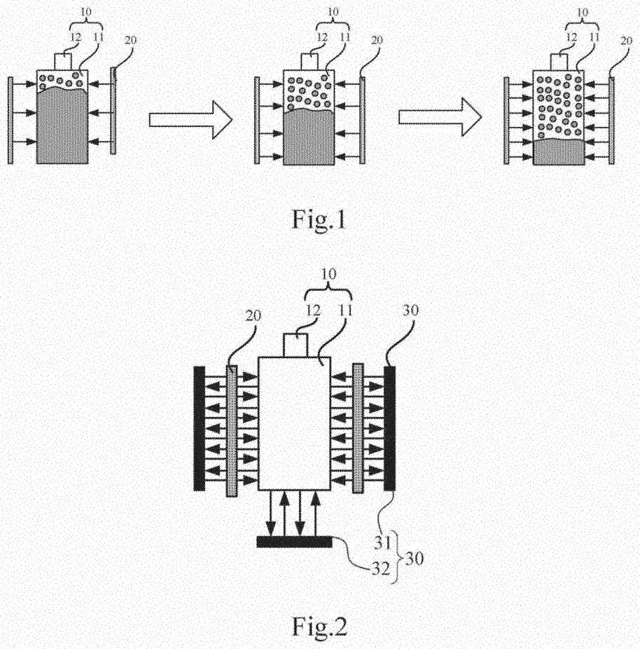

With respect to the evaporation process, the evaporation source for the evaporation material is its core. The associated evaporation source consists of a crucible and a heater used to heat the evaporation material in the crucible to achieve the basic function of the material eruption. However, as shown in FIG. 1, as the evaporation process proceeds, the evaporation material becomes less and less in the crucible 10, and the position gets lower and lower. At this time, if it is necessary to keep the evaporation amount of the evaporation material constant, it is necessary to increase the amount of heat generated by the heater 20 (the more denser the arrow is, the more heat is generated). In this case, excessive heat is dissipated to the outside of the evaporation source, and the mask for evaporation above the evaporation source is thermally deformed, thereby affecting precision of the evaporation.

An embodiment of the present disclosure provides an evaporation source for improving the problem that heat leaked from the evaporation source is too high in the prior art, thereby causing the mask to be severely thermally deformed.

An embodiment of the present disclosure provides an evaporation source, as shown in FIG. 2, including a crucible 10 and a heater 20 for generating heat radiation. The crucible 10 includes a crucible body 11 and a nozzle 12 disposed on a top surface of the crucible body 11. Except for the top surface of the crucible body 11, at least one side of the remaining sides of the crucible body 11 is provided with a heat adjusting assembly 30 (for example, in FIG. 2, the heat adjusting assembly 30 is disposed on both the side and the bottom surfaces); the heat adjusting assembly 30 is used to convect heat radiation between the heat adjusting assembly 30 and the crucible body 11, where a gap exists between the heat adjusting assembly 30 and the crucible body 11.

It should be noted that, first, the embodiment of the present disclosure does not define the specific structure of the crucible 10 and the heater 20, and also does not define the arrangement position of the heater 20 with respect to the crucible 10, which, for example, may be the same as that of the prior art.

Second, an object having a temperature higher than absolute zero may generate heat radiation. The higher the temperature, the greater the total energy radiated. The heater 20 generates heat radiation for heating the evaporation material inside the crucible body 11.

The heat adjusting assembly 30 is used to convect heat radiation between the heat adjusting assembly 30 and the crucible body 11, which means that there is a reflection cavity formed between the heat adjusting assembly 30 and the crucible body 11. A portion of the heat radiation generated by the heater 20 is absorbed by the crucible body 11 to heat the evaporation material, and the unabsorbed portion remains in the reflection cavity, which is reflected by the crucible body 11 to the heat adjusting assembly 30 and then reflected by the heat adjusting assembly 30 to the crucible body 11. The portion is absorbed by the crucible body 11 again for heating the evaporation material.

Third, a size of the gap between the heat adjusting assembly 30 and the crucible body 11 is not limited, and may be appropriately set according to the specific structure, as long as the heat adjusting assembly 30 is not attached to the crucible body 11.

Those skilled in the art should understand that, in order to convect heat radiation between the heat adjusting assembly 30 and the crucible body 11, the heat adjusting assembly 30 should be capable of reflecting heat radiation to the crucible body 11.

In addition, taking the crucible body 11 formed in a rectangular parallelepiped shape as an example, the heat adjusting assembly 30 may be disposed only on the bottom surface of the crucible body 11, or may be disposed only on certain side surfaces of the crucible body 11, or except for the top surface of the crucible body 11, a heat adjusting assembly 30 is disposed on each of the remaining side surfaces. Of course, in the case where a plurality of heat regulation assemblies 30 are provided in the evaporation source, structures of the plurality of heat regulation assemblies 30 are not necessarily identical.

Fourth, it may be the case that the heater 20 is located on the side of the heat adjusting assembly 30 away from the crucible body 11, and the heat radiation generated by the heater 20 may pass through the heat adjusting assembly 30 and then may be convected between the heat adjusting assembly 30 and the crucible body 11. It may also be the case that the heater 20 is located between the heat adjusting assembly 30 and the crucible body 11 to convect heat radiation between the heat adjusting assembly 30 and the crucible body 11. Also, there may other ways.

Fifth, during the evaporation process, the material on the surface of the evaporation material is preferably ejected from the nozzle 12, and as the evaporation process proceeds, the evaporation material in the crucible body 11 becomes less and less, and the surface of the evaporation material gradually decreases, so that the space from the surface of the evaporation material to the nozzle 12 is increasingly larger. In order to ensure the amount of ejection of the nozzle 12 is constant, it is necessary to ensure that the internal pressure between the surface of the material between the nozzle 12 is always constant. One of the more mature methods is to increase the heating temperature for the evaporation material. \textcircled{1}, \textcircled{2}, and \textcircled{3} of FIG. 1 respectively indicate three states as the evaporation process proceeds, in which the heat radiation supply of the heater 20 (the heat radiation is indicated by an arrow) is increased in the prior art, in order to ensure the amount of ejection of the nozzle 12 to be constant, and cause more heat radiation to be dissipated from the top of the evaporation source to the outside.

As shown in FIG. 2, the embodiment of the present disclosure convects the heat radiation generated by the heater 20 in the reflection cavity formed by the heat adjusting assembly 30 and the crucible body 11 to improve the utilization of the heat radiation generated by the heater 20. Compared to the prior art, the supply of heat radiation of the heater 20 can be reduced, while the heat radiation dissipated to the outside of the evaporation source can be reduced.

In the evaporation source provided by the embodiment of the present disclosure, the heat radiation component 30 is disposed outside the crucible body 11 such that the heat radiation generated by the heater 20 is convected between the heat adjusting assembly 30 and the crucible body 11, thereby creating absorptivity in the crucible body for the heat radiation. Compared with the prior art, during the use of the evaporation source provided by the present disclosure (no matter which stage the evaporation process is carried out), the heat radiation supplied by the heater 20 is lower than that of the prior art, and the utilization rate of the heat radiation is higher than that of the prior art. In this regard, more heat radiation generated by the heater 20 may be reflected to the surface of the evaporation material to heat the evaporation material, thereby improving the utilization efficiency of the heat radiation and avoiding or reducing the rise of the heating temperature of the heater 20. As a result, less heat radiation is dissipated from the top of the evaporation source to the outside, so that the problem of the mask for evaporation on the upper portion of the evaporation source being thermally expanded and deformed by heat is improved, and the evaporation precision is improved.

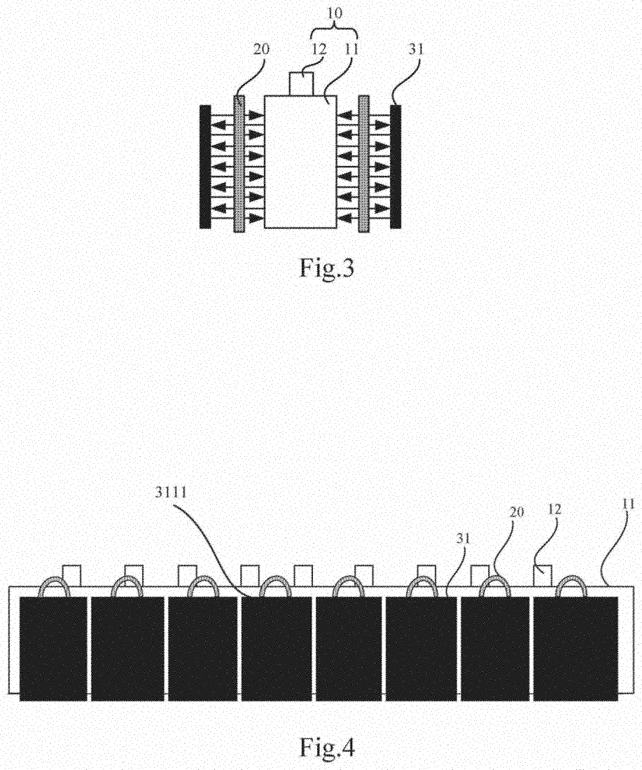

In order to minimize the waste of heat radiation generated by the heater 20, in some embodiments, as shown in FIG. 3, the heat adjusting assembly 30 includes a first heat adjusting member 31, and both the first heat adjusting member 31 and the heater 20 are disposed on the side surface of the crucible body 11, and the heater 20 is disposed between the first heat adjusting member 31 and the crucible body 11, where the side surface and the top surface of the crucible body 11 are intersected.

Taking the crucible body 11 formed in a rectangular parallelepiped shape as an example, the crucible body 11 includes four side surfaces, each of which may be provided with a heater 20, or only some of the side surfaces may be provided with a heater 20. Similarly, each side surface may be provided with a first heat adjusting member 31, or only some of side surfaces may be provided with a first heat adjusting member 31. The heater 20 and the first heat adjusting member 31 are not necessarily disposed at the same time on a side where the side surface is located. If the heater 20 is disposed on a side where the side surface is located, and the first heat adjusting member 31 is also provided on this side, the first heat adjusting member 31 is disposed on a side of the heater 20 away from the crucible body 11.

In some embodiments, as shown in FIG. 4, the crucible body 11 is in a form of a rectangular parallelepiped, and the heater 20 and the first heat adjusting member 31 are disposed on a side where the side surface surrounded by a length and a height of the crucible body 11 is located.

The height of the crucible body 11 refers to a dimension of the crucible body 11 in the ejection direction of the evaporation material. The length and width of the crucible body 11 are both perpendicular to the height of the crucible body 11, and the length is longer than the width.

That is to say, the crucible body 11 includes four side surfaces, and the heater 20 and the first heat adjusting member 31 are disposed on the side where two side surfaces surrounded by the length and the height is located.

The crucible 10 used in the evaporation source is generally a line source type crucible, and the crucible body 11 is a rectangular parallelepiped. The top surface of the crucible body 11 is provided with a plurality of nozzles 12. Since the length of the crucible body 11 is too long, the heating effect of the heater 20, disposed on the side where the side surface surrounded by the length and height is located, on the evaporation material in the central portion of the crucible body 11 cannot be guaranteed, the heating effect on this side of crucible body 11 is especially important in order to ensure the heating effect of the evaporation material in the crucible body 11. Based on this, the embodiment of the present disclosure can increase the heating effect of the heater 20 disposed on the side where the side surface surrounded by the length and height is located, by providing the first heat adjusting member 31 on this side, thereby reducing the supply of heat radiation to the heater 20 disposed on this side, and further reducing the amount of heat dissipated to the outside of the evaporation source.

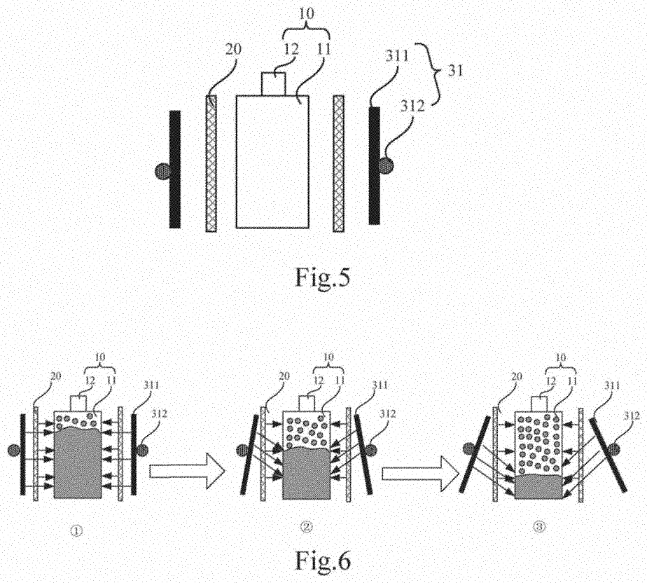

In some embodiments, as shown in FIG. 5, the first heat adjusting member 31 includes a first reflection plate 311 along an ejection direction of the crucible 10, and a height of the first reflection plate 311 is lower than a height of the crucible body 11.

That is to say, the first reflection plate 311 is not provided beyond the top surface of the crucible body 11. The length and width of the first reflection plate 311 are not limited herein, and may be greater than or equal to the length and width of the crucible body 11, for example.

During the evaporation process, when the evaporation material reaches the nozzle 12, it is already in an evaporation state, and the degree of heat radiation in the evaporation source can ensure the normal ejection of the evaporation material, so as to avoid the situation that the heat radiation is reflected out of the evaporation source by the first reflection plate 311 due to the first reflection plate 311 being located too high. Here, the height of the first reflection plate 311 is provided lower than the height of the crucible body 11.

In some embodiments, as shown in FIG. 5, the first heat adjusting member 31 further includes a control structure 312 connected to the first reflection plate 311, and configured to drive the first reflection plate 311 to rotate so as to adjust an angle between the first reflection plate 311 and a side surface corresponding to the first reflection plate 311.

Here, the specific structure of the control structure 312 is not limited so long as the first heat adjusting member 31 can be rotated. For example, the control structure 312 includes a servo motor. The rotating shaft of the servo motor is connected to the first reflection plate 311. The servo motor rotates the first reflection plate 311 by controlling rotation of the rotating shaft.

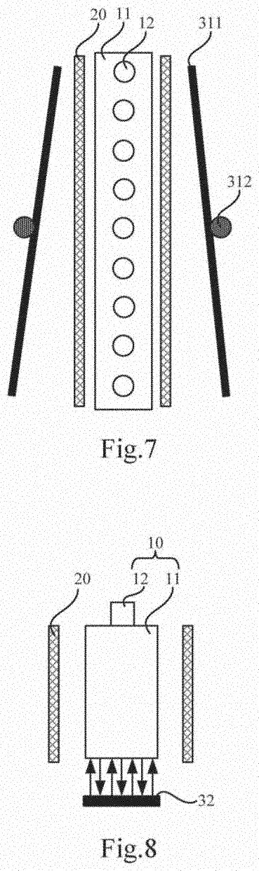

The manner of rotating the first reflection plate 311 is not limited herein, and may be as shown in FIG. 6 (FIG. 6 is a side view). As the evaporation process proceeds, the top of the first reflection plate 311 gradually approaches the top surface of the crucible body 11, and the bottom thereof is gradually separated away from the bottom surface of the crucible body 11. In this regard, the first reflection plate 311 is changed from a state perpendicular to the bottom surface of the crucible body 11 into a state at an angle with the bottom surface of the crucible body 11, so that the heat radiation reflected by the first reflection plate 311 is closer to the bottom of the crucible body 11. It is also possible to have a side portion of the first reflection plate 311 gradually approaching the side surface of the crucible body 11 as shown in FIG. 7 (FIG. 7 is a top view), and the opposite other side portion is gradually separated away from the side surface of the crucible body 11. In this regard, the first reflection plate 311 is always perpendicular to the bottom surface of the crucible body 11, and the angle with the side surface of the crucible body 11 is gradually changed. Of course, it is also possible that both rotation modes exist simultaneously. As the evaporation process proceeds, the angle of the first reflection plate 311 is controlled by the control structure 312 so that more heat radiation can be reflected to the surface of the evaporation material, thereby further increasing the utilization rate of the heat radiation and reducing requirements of the heating temperature of the heater 20.

The embodiment of the present disclosure adjusts the angle of the first reflection plate 311 via the control structure 312, so that the first reflection plate 311 can reflect the heat radiation to the place where the evaporation material is located, while radiation of the heat radiation is avoided from the top of the evaporation source, the range of heat radiation of the heater 20 is optimized, and the amount of heat radiated from the evaporation source is effectively controlled.

In some embodiments, the first reflection plate 311 includes a plurality of first sub-plates that are independently controlled by the control structure 312.

Here, the first reflection plate 311 is provided as a structure including a plurality of independent first sub-plates 3111, wherein the plurality of first sub-plates 3111 are independently controlled by the control structure 312. Thus, on the one hand, the angle between the first sub-plate 3111 with different positions and the crucible body 11 can be independently adjusted, thereby further improving the utilization rate of heat radiation. On the other hand, the plurality of first sub-plates 3111 can be independently replaced, thereby reducing the production cost.

In some embodiments, in order to improve the reflection effect of the first reflection plate 311 on the heat radiation, the first reflection plate 311 is selected as a double mirror plate.

In some embodiments, as shown in FIG. 8, the heat adjusting assembly 30 includes a second heat adjusting member 32 disposed on a bottom surface of the crucible body 11, and the bottom surface is disposed opposite the top surface.

During the evaporation process, the bottom of the crucible body 11 is always provided with an evaporation material. By providing the second heat adjusting member 32 on the bottom surface of the crucible body 11, the heating effect of the evaporation material on the bottom of the crucible body 11 can be improved, thereby reducing requirements of the heating temperature of the heater 20.

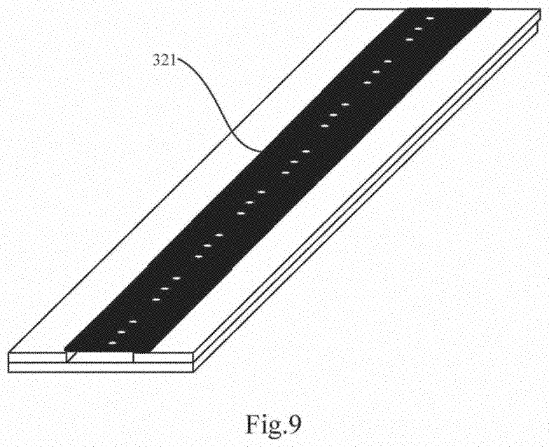

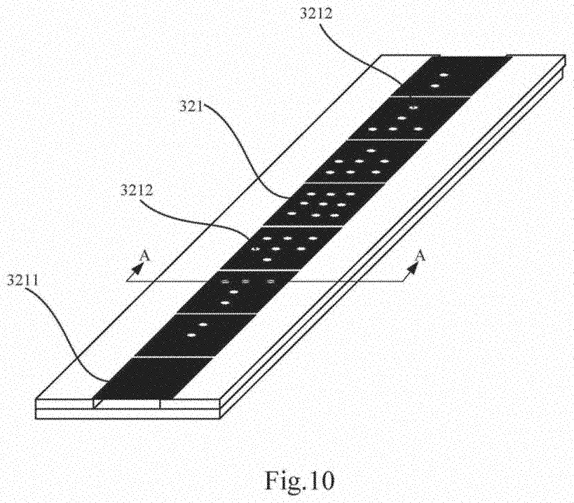

In some embodiments, as shown in FIGS. 9 and 10, the second heat adjusting member 32 includes a second reflection plate 321 on which a hollowed-out pattern 3212 is disposed.

The specific shape of the hollowed-out pattern 3212 and the manner of arrangement of the hollowed-out pattern 3212 on the second reflection plate 321 are not limited. Different numbers of hollowed-out patterns 3212 may be disposed in different regions as needed, and shapes of the hollowed-out patterns 3212 disposed on the second reflection plate 321 are not necessarily identical. As an example, the second reflection plate 321 may be a double mirror plate, where the shape of the second reflection plate 321 is the same as that of the bottom surface of the crucible body 11, and the second reflection plate 321 is disposed directly below the crucible body 11.

In the embodiment of the present disclosure, the second reflection plate 321 having the hollowed-out pattern 3212 is disposed on the bottom of the crucible 10 so that the reflecting ability of the second reflection plate 321 in different regions is different, thereby ensuring uniformity of heating on the bottom portion of the crucible body 11.

In some embodiments, as shown in FIG. 10, along the extending direction of the crucible body 11, a density of the hollowed-out pattern 3212 on the second reflection plate 321 is firstly increased and then decreased.

The density of the hollowed-out pattern 3212 is increased, which means that the number of the hollowed-out patterns 3212 may be increased, or the area of the hollowed-out pattern 3212 may be increased to increase a proportion of the hollowed-out region. The manner in which the density is increased or decreased does not necessarily increase by a certain rule, as long as the overall tendency to increase or decrease is sufficient.

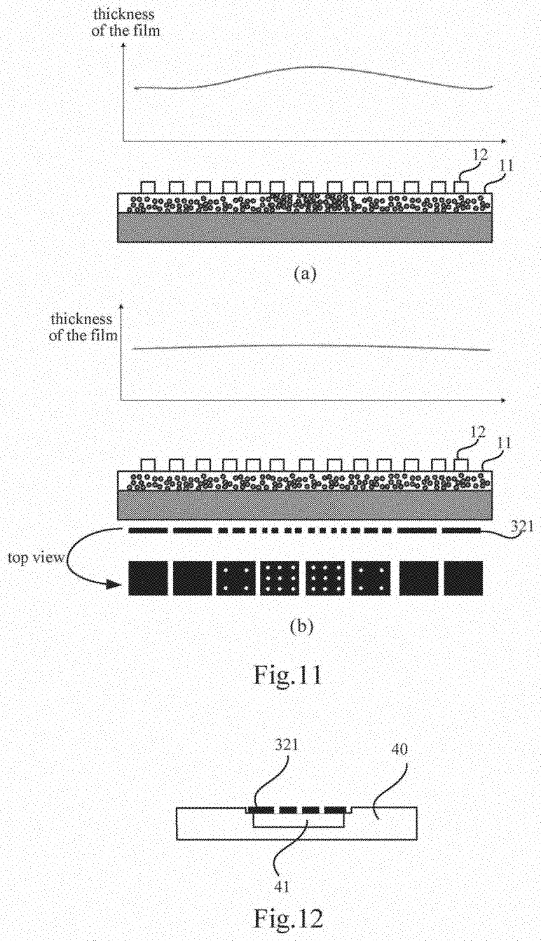

Here, in the process of evaporating the evaporation material by the actual evaporation source, the heat distribution is likely to be uneven inside the evaporation source along the length direction of the crucible body 11, and a thickness of the film vapor-deposited on the substrate may be unevenly distributed, i.e., the film thickness has poor uniformity. As shown in (a) of FIG. 11, when the second reflection plate 321 is not provided, the film thickness distribution may be uneven, and the heat in the middle portion of the crucible 10 is high, thereby resulting in relatively more evaporation material ejected in the middle portion, and causing a film layer that is thick in the middle portion and thin on both sides. With respect to such a film thickness distribution, as shown in (b) of FIG. 11, the second reflection plate 321 is provided on the bottom of the crucible 10. A larger number of hollowed-out patterns are provided at the second reflection plate 321 corresponding to the middle portion having a thicker film thickness, or the area of the hollowed-out pattern 3212 is designed to be larger to reflect less heat to the inside of the crucible 10; and a smaller number of hollowed-out patterns 3212 are provided at the second reflection plate 321 corresponding to the thinner side regions of the film layer, or the area of the hollowed-out pattern 3212 is designed to be smaller, in which manner the internal heat balance of the crucible 10 is adjusted to make the film thickness distribution more uniform.

In the embodiment of the present disclosure, the second reflection plate 321 having different densities of the hollowed-out pattern 3212 along the length direction of the crucible 10 is added, so that the reflecting capability of the second reflection plate 321 for heat radiation in different regions is different, thereby reflecting different amounts of heat radiation to the inside of the crucible 10, and realizing heat regulation inside the crucible 10, so as to ensure uniformity of the thickness of the film layer.

In some embodiments, as shown in FIG. 10, the second reflection plate 321 includes a plurality of second sub-plates, and at least a portion of the second sub-plates are provided with a hollowed-out pattern 3212.

That is to say, as shown in FIG. 10, it is not necessary to provide the hollowed-out pattern 3212 on each of the second sub-plates. Of course, the hollowed-out pattern 3212 may be provided on each of the second sub-plates as needed. The hollowed-out pattern 3212 provided on each of the second sub-plates is not necessarily identical, for example, it may be denser in the middle and thin on both sides.

In the embodiment of the present disclosure, the second reflection plate 321 is provided as a structure including the plurality of second sub-plates 3211 to facilitate the independent replacement of the second sub-plate 3211, thereby both ensuring the reflection effect on the heat radiation and reducing the production cost.

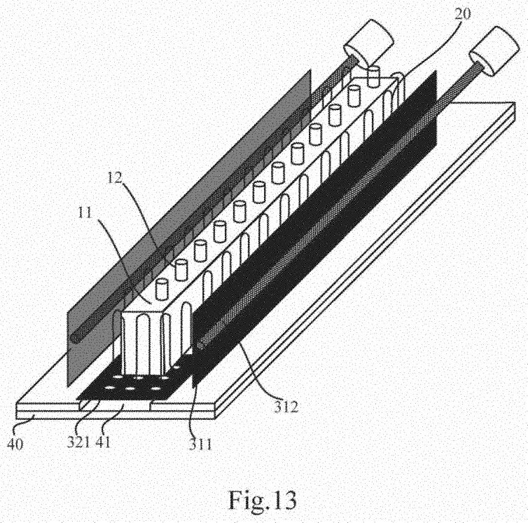

In order to prevent heat radiation from being radiated from the hollowed-out pattern 3212 on the second reflection plate 321, it is not directly reflected back to the crucible body 11 by a base. In some embodiments, as shown in FIGS. 12 and 13, the evaporation source further includes a base 40 on which a groove 41 is disposed; the second reflection plate 321 is disposed at the opening of the groove 41, directly facing the bottom of the groove 41.

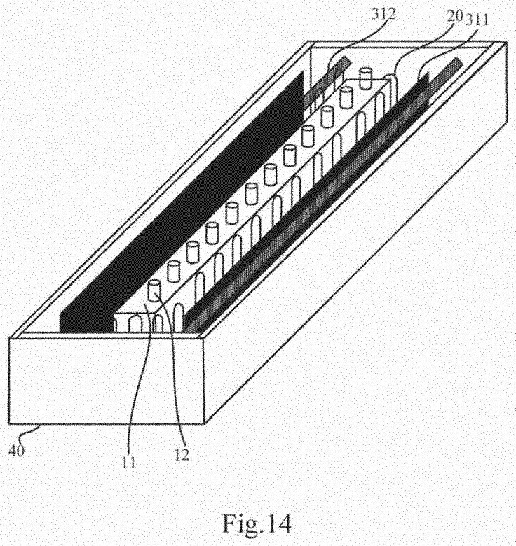

As shown in FIG. 14, the crucible 10, the heater 20, and the heat adjusting assembly 30 are all disposed in an evaporation source housing, and the second reflection plate 321 is disposed on the base of the evaporation source housing. The same evaporation source may not only include a first heat adjusting member 31, but also include a second heat adjusting member 32.

The above description is only the specific embodiment of the present disclosure, but the scope of the present disclosure is not limited thereto, and those skilled in the art can easily conceive of changes or substitutions within the technical scope of the present disclosure. Those changes or substitutions should be covered within the scope of protection of the present disclosure. Therefore, the scope of protection of the present disclosure should be determined by the scope of the claims.

1. An evaporation source comprising:
a crucible comprising:
a crucible body having a top surface; and
a nozzle disposed in the crucible body;
a heater disposed outside the crucible body for generating heat radiation; and
a heat adjusting assembly disposed on at least one of remaining sides except for a side of the top surface of the crucible body, wherein a gap exists between the heat adjusting assembly and the crucible body, and the heat adjusting assembly is configured for convecting heat radiation between the heat adjusting assembly and the crucible body.

2. The evaporation source according to claim 1, wherein the crucible body further comprises a bottom surface opposite to the top surface and a side surface connecting the top surface and the bottom surface, and the heat adjusting assembly is disposed at a side surface of the crucible body.

3. The evaporation source according to claim 2, wherein the heater is disposed on the side surface of the crucible body and located between the heat adjusting assembly and the crucible body, wherein the gap exists between the heat adjusting assembly and the crucible body, and the heat adjusting assembly and the heater.

4. The evaporation source according to claim 3, wherein the heat adjusting assembly comprises a first heat adjusting member.

5. The evaporation source according to claim 4, wherein the crucible body is in a form of a rectangular parallelepiped, and the heater and the first heat adjusting member are disposed on the side surface formed by a length and a height of the crucible body.

6. The evaporation source according to claim 3, wherein the first heat adjusting member comprises a first reflection plate along an ejection direction of the crucible, and a height of the first reflection plate is lower than a height of the crucible body.

7. The evaporation source according to claim 6, wherein the first heat adjusting member further comprises:
a control structure connected with the first reflection plate, the control structure being configured to drive the first reflection plate to rotate so as to adjust an angle between the first reflection plate and a side surface corresponding to the first reflection plate.

8. The evaporation source according to claim 7, wherein the first reflection plate comprises a plurality of first sub-plates independently controlled by the control structure.

9. The evaporation source according to claim 6, wherein the first reflection plate is a dual mirror plate.

10. The evaporation source according to claim 2, wherein the heat adjusting assembly comprises:
a second heat adjusting member disposed on the bottom surface of the crucible body.

11. The evaporation source according to claim 10, wherein the second heat adjusting member comprises a second reflection plate on which a hollowed-out pattern is provided.

12. The evaporation source according to claim 11, wherein a density of the hollowed-out pattern on the second reflection plate firstly increases and then decreases along an extending direction of the crucible body.

13. The evaporation source according to claim 11, wherein the second reflection plate comprises a plurality of second sub-plates, and the hollowed-out pattern is provided on at least some of second sub-plates in the plurality of second sub-plates.

14. The evaporation source according to claim 11, further comprising a base provided with a groove, wherein the second reflection plate is disposed at an opening of the groove and faces a bottom of the groove.
